(19) United States
(12) Patent Application Publication
(10) Pub. No.: US 2016/0088724 A1
(43) Pub. Date: Mar. 24, 2016

(54) GROUNDING PATTERN STRUCTURE FOR HIGH-FREQUENCY CONNECTION PAD OF CIRCUIT BOARD

(71) Applicant: ADVANCED FLEXIBLE CIRCUITS CO., LTD., TAOYUAN COUNTY (TW)

(72) Inventors: CHIH-HENG CHUO, TAOYUAN COUNTY (TW); GWUN-JIN LIN, TAOYUAN COUNTY (TW); KUO-FU SU, TAOYUAN COUNTY (TW)

(21) Appl. No.: 14/958,006

(22) Filed: Dec. 3, 2015

Related U.S. Application Data
(62) Division of application No. 13/895,444, filed on May 16, 2013.

(30) Foreign Application Priority Data
Mar. 20, 2013 (TW) 102109815

(51) Int. Cl. H05K 1/02; H01P 3/02; H05K 1/11

(52) U.S. Cl. CPC H05K 1/0224; H05K 1/0245; H05K 1/0253; H05K 1/117; H05K 1/0219; H01P 3/026; H05K 2201/058

(57) ABSTRACT

Disclosed is a grounding pattern structure for high-frequency connection pads of a circuit board. A substrate of the circuit board includes a component surface on which at least a pair of high-frequency connection pads. At least a pair of differential mode signal lines are formed on the substrate and connected to the high-frequency connection pads. The grounding surface of the substrate includes a grounding layer formed at a location corresponding to the differential mode signal lines. The grounding surface of the substrate includes a grounding pattern structure formed thereon to correspond to a location adjacent to the high-frequency connection pads. The grounding pattern structure is electrically connected to the grounding layer. The component surface of the substrate can be provided with a connector mounted thereto with signal terminals of the connector soldered to the high-frequency connection pads.

### CROSS-REFERENCES TO RELATED APPLICATIONS

This application is a division of Ser. No. 13/895,444 filed May 16, 2013, currently pending.

### BACKGROUND OF THE INVENTION

1. Field of the Invention

The present invention relates to a design for improving quality of high-frequency signal transmission of a circuit board, and in particular to a grounding pattern structure for high-frequency connection pads of a circuit board.

2. The Related Arts

Modern electronic devices require transmission of data that is increasingly expanded through signal lines. Consequently, the number of signal lines involved in signal transmission is increased and the frequency used is higher. The mostly commonly adopted solution is differential mode signal transmission that helps reduce electromagnetic interference (EMI). For example, signal transmission with USB (Universal Serial Bus), LVDS (Low Voltage Differential Signaling), and EDP (Embedded Display Port) are generally done with such a transmission technology to reduce EMI.

The differential mode signal transmission technology is effective in improving potential problem occurring in signal transmission. However, incorrect design may often result in problems associated with signal reflection, electromagnetic wave dispersion, and loss of signal in transmission and reception, distortion of signal waveform in practical applications. These problems get even more severe for circuit boards having smaller thickness. These problems are caused by several factors, such as poor impedance matching in lengthwise direction of the differential mode signal lines, poor control of capacitive coupling effect between a differential mode signal line and a grounding layer, poor control of capacitive coupling effect between a high-frequency connection pad and a grounding layer, and impedance mismatching between a differential mode signal line and a high-frequency connection pad.

Further, for example, when a circuit board is inserted into an insertion slot of a female connector, a differential mode signal line and a high-frequency connection pad may induce parasitic capacitance and inductance with respect to conductive terminals contained inside the female connector that cause reflection and loss of high-order harmonics thereby affecting the quality of high-frequency signal transmission.

Further, for example, in an application that a connector is set on a circuit board, a differential mode differential line and a high-frequency connection pad may induce parasitic capacitance and inductance with respect to signal terminals of the connector that also affect the quality of high-frequency signal transmission.

Modern technology provides various solutions for overcoming the problems of circuit boards associated with EMI occurring in the lengthwise direction of a differential mode signal line and impedance matching. However, at the connection, as well as neighboring area, between a differential mode signal line and a high-frequency connection pad zone laid on a circuit board, due to the limitation imposed by the line width of the differential mode signal line (which is an extremely small width) and the size specifications of signal terminals and components of a connector (which are generally of much larger sizes than the line width of the signal line), the state of the art in the technical field does not have an effective solution to ensure the quality of signal transmission.

Further, for the applications where a circuit board is inserted into an insertion slot of a female connector or a connector is mounted on a circuit board, in respect of the quality issue of high-frequency signal transmission between a differential mode signal line and a high-frequency connection pad zone and conductive terminals of the female connector or the signal terminals of the connector, there is so far no effective solution.

### SUMMARY OF THE INVENTION

Thus, an object of the present invention is to provide a grounding pattern structure for high-frequency connection pads of a circuit board, which comprises a grounding pattern structure formed at a location corresponding to high-frequency connection pads of the circuit board in such a way that the grounding pattern structure and the high-frequency connection pads provide for excellent impedance match with respect to each other so as to reduce reflection and loss of high order harmonics in transmitting signals and thus improving signal transmission quality of differential mode signal lines of the circuit board.

The technical solution that the present invention adopts to address the problems of the prior art is that a component surface of a substrate comprises at least a pair of high-frequency connection pads formed thereon and at least a pair of differential mode signal lines formed on the substrate and connected to the high-frequency connection pads. The grounding surface of the substrate comprises a grounding layer formed thereon at a location corresponding to the differential mode signal lines, whereby the grounding layer and the differential mode signal lines form therebetween first capacitive coupling. The grounding surface of the substrate comprises a grounding pattern structure corresponding to a location adjacent to the high-frequency connection pads and the grounding pattern structure is electrically connected to the grounding layer and forms, with respect to the high-frequency connection pads, second capacitive coupling that matches the first capacitive coupling.

According to the present invention, the grounding pattern structure comprises a hollow section or a structure of hollow section or can alternatively be a hollow-patterned structure that comprises a plurality of grid openings, square openings, rectangular openings, rhombus openings, or circuit openings, of which the size is fixed or variable.

According to the present invention, the grounding layer and the grounding pattern structure further comprise a boundary pattern zone therebetween. The boundary pattern zone corresponds to a location adjacent to the connection between the high-frequency connection pads and the differential mode signal lines. The boundary pattern zone comprises a hollow-patterned structure comprising a plurality of grid openings, square openings, rectangular openings, rhombus openings, or circuit openings of which the size is fixed or variable.

With the technical solution adopted in the present invention, the grounding layer of the circuit board and the differential mode signal lines formed on the circuit board can form therebetween first capacitive coupling that matches second capacitive coupling formed between the grounding pattern structure and the high-frequency connection pads, whereby in transmitting a high frequency signal that is carried by the differential mode signal lines through the extension section to the high-frequency connection pads, impedance matching effect between the two sections can be achieved to thereby reduce the potential risk of erroneous transmission of high-frequency differential mode signal and ensure transmission quality of the high frequency signal.

Further, according to the present invention, the boundary pattern zone allows capacitive coupling between the grounding layer and the differential mode signal lines to match the capacitive coupling between the boundary pattern zone and the differential mode signal lines, whereby in transmitting a high frequency signal carried by the differential mode signal lines through the extension section to a boundary area of the high-frequency connection pads, the impedance matching effect can be achieved to thereby reduce the potential risk of erroneous transmission of high-frequency differential mode signal and ensure transmission quality of the high frequency signal.

In an application that the circuit board is mounted to a connector, when the differential mode signal lines transmit a high-frequency differential mode signal and apply the high-frequency differential mode signal to the signal terminals, with the arrangement of the grounding pattern structure according to the present invention, in transmitting a high-frequency signal carried by the differential mode signal lines through the extension section to the high-frequency connection pads, the impedance matching effect between the two sections can be achieved to thereby reduce the potential risk of erroneous transmission of high-frequency differential mode signal and ensure transmission quality of the high frequency signal.

### BRIEF DESCRIPTION OF THE DRAWINGS

The present invention will be apparent to those skilled in the art by reading the following description of preferred embodiments of the present invention, with reference to the attached drawings, in which:

FIG. 1 is an exploded view showing a first embodiment according to the present invention;

FIG. 2 is a perspective view of the first embodiment according to the present invention;

FIG. 3 is a cross-sectional view taken along line 3-3 of FIG. 2;

FIG. 4 is a cross-sectional view taken along line 4-4 of FIG. 2;

FIG. 5 is a bottom view of FIG. 2;

FIG. 6 is a schematic view showing a grounding pattern structure of FIG. 5 that is further coupled to a boundary pattern zone;

FIG. 6A shows a first variation of the grounding pattern structure;

FIG. 6B shows a second variation of the grounding pattern structure;

FIG. 6C shows a third variation of the grounding pattern structure;

FIG. 6D shows a fourth variation of the grounding pattern structure;

FIG. 6E shows a fifth variation of the grounding pattern structure;

FIG. 6F shows a variation of the grounding pattern structure;

FIG. 6G shows a variation of the grounding pattern structure;

FIG. 6H shows a variation of the grounding pattern structure;

FIG. 6I shows a variation of the grounding pattern structure;

FIG. 7 is a schematic exploded view showing a circuit board according to the first embodiment of the present invention insertable into a female connector;

FIG. 8 is an exploded view showing a second embodiment according to the present invention;

FIG. 9 is a schematic side elevational view showing the second embodiment according to the present invention;

FIG. 10 is a schematic view showing a grounding pattern structure of FIG. 8; and

FIG. 11 is a schematic side elevational view showing high-frequency connection pads of FIG. 9 are further arranged in such a way that each high-frequency connection pad comprises an isolation zone.

### DETAILED DESCRIPTION OF THE PREFERRED EMBODIMENTS

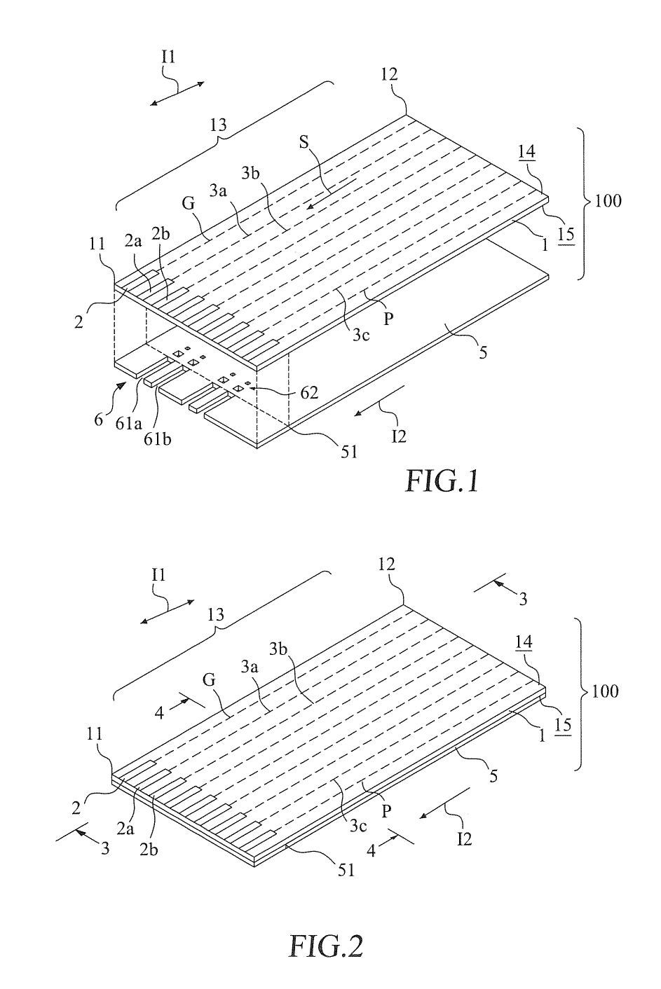

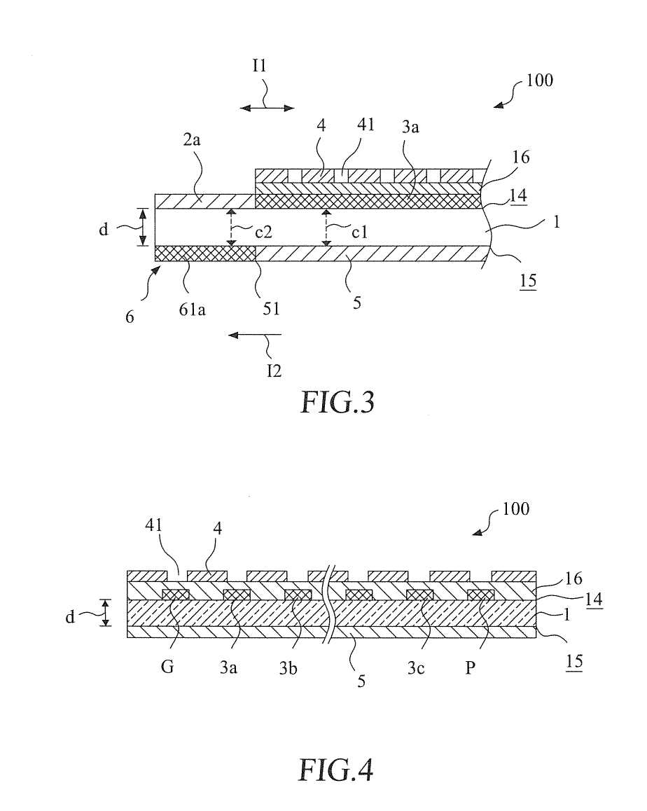

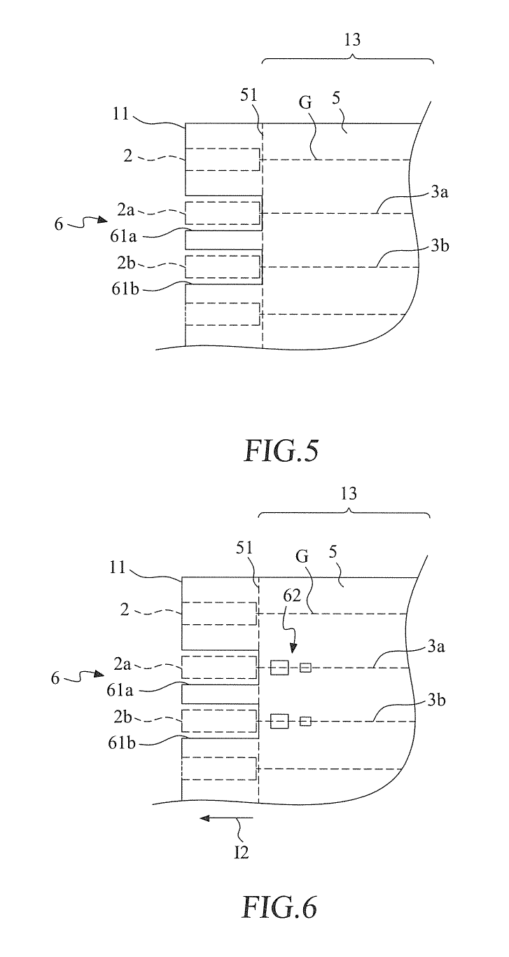

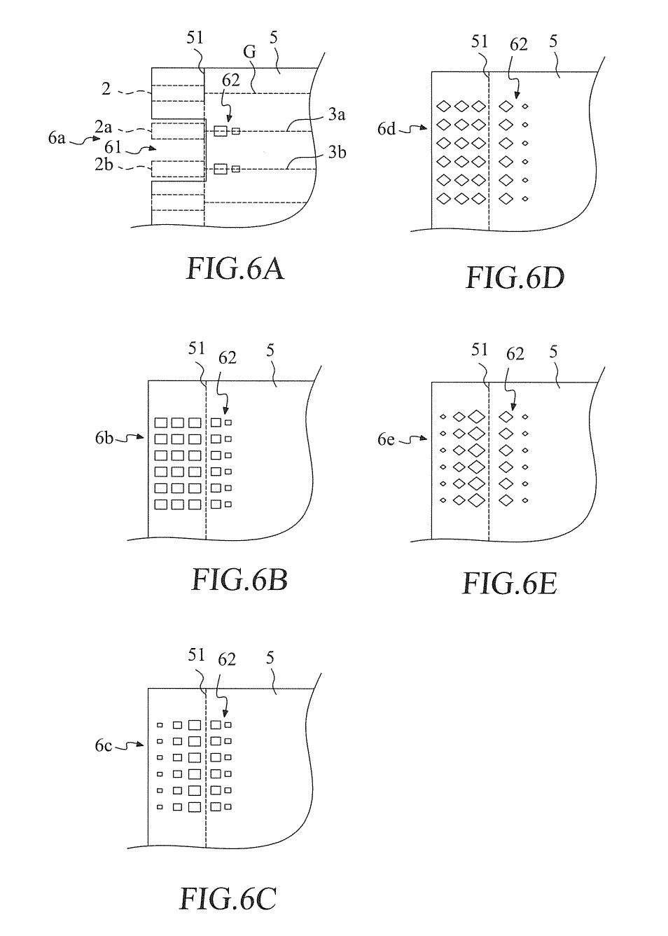

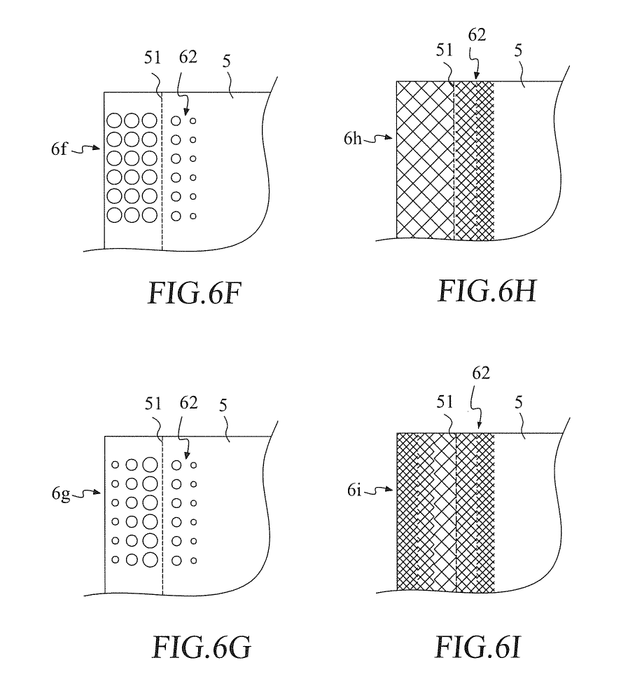

With reference to the drawings and in particular to FIGS. 1 and 2, of which FIG. 1 is an exploded view showing a first embodiment according to the present invention and FIG. 2 is a perspective view showing the first embodiment according to the present invention, a circuit board 100 of the instant embodiment comprises a substrate 1, which comprises a first end 11, a second end 12 (as also shown in FIGS. 5, 6), and an extension section 13 that extends in an extension direction 11 (as also shown in FIGS. 3, 7, 8) between the first end 11 and the second end 12. In a preferable embodiment of the present invention, the circuit board 100 is a flexible circuit board having a flexible substrate.

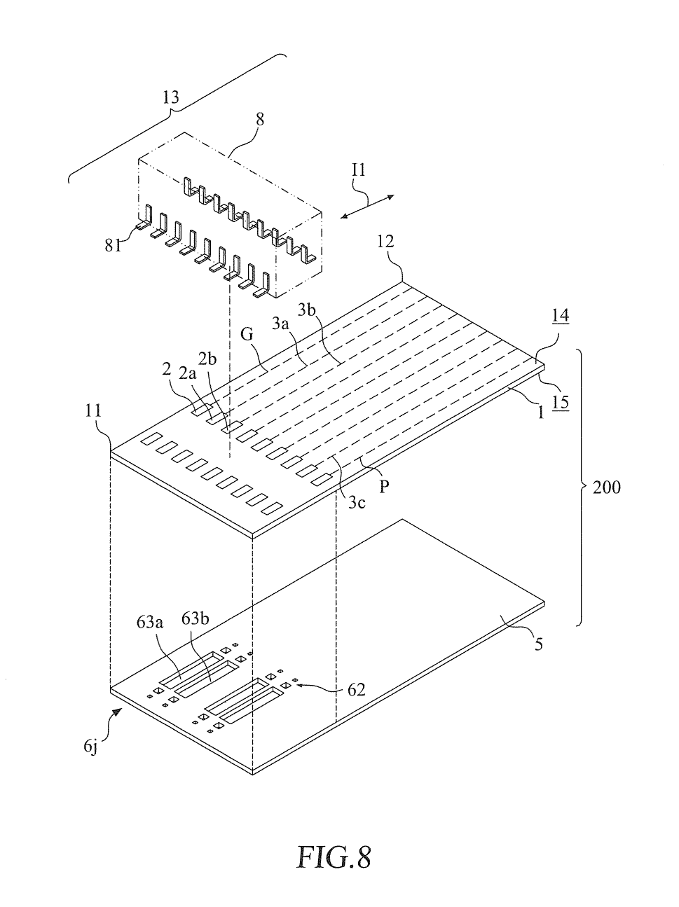

A plurality of the connection pads 2 (as also shown in FIGS. 5, 6, 6A) are formed on a component surface 14 of the substrate 1 (as also shown in FIGS. 3, 4, 7, 8, 9, 11) in a manner of being adjacent to and isolated from each other at a location adjacent to the first end 11 of the substrate 1. The connection pads 2 comprise at least a pair of high-frequency connection pads 2a, 2b (as also shown in FIG. 8). It is understood that the connection pads 2 may include well-known solder pads for soldering purpose and contact pads for electrically contacting purpose.

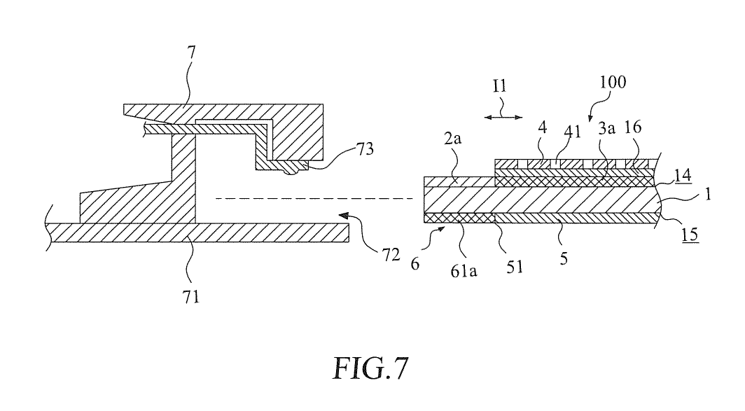

The extension section 13 is provided with at least a pair of differential mode signal lines 3a (as also shown in FIGS. 7, 8, 9, 11), 3b for transmitting at least a high-frequency differential mode signal S as shown in FIG. 1. The differential mode signal lines 3a, 3b are respectively connected to the high-frequency connection pads 2a, 2b. The extension section 13 is also provided with a the common mode signal line 3c (as also shown in FIGS. 4, 8), a power line P (as also shown in FIGS. 4, 8), and a grounding line G (as also shown in FIGS. 4, 5, 6, 6A, 8), all these lines being respectively connected to designated ones of the connection pads 2.

Also referring to FIGS. 3 and 4, the substrate 1 has a predetermined substrate thickness d and has two surfaces of which one surface serves as the component surface 14 of the substrate 1, while the other surface serves as a grounding surface 15 (as also shown in FIGS. 1, 2, 8, 9, 11). In an actual product, an insulation cover layer 16 (as also shown in FIGS. 1, 2, 3, 4, 8, 9, 11) may be further formed on the component surface 14 (as also shown in FIG. 7) of the substrate 1 and a shielding layer 4 (as also shown in FIG. 7) is further formed on the insulation cover layer 16. An impedance control structure 41 (as also shown in FIG. 7) is further formed on the shielding layer 4.

The grounding surface 15 of the substrate 1 comprises a grounding layer 5 (as also shown in FIGS. 2, 8, 9, 11) formed on a portion thereof corresponding to the differential mode signal lines 3a, 3b (FIGS. 4), whereby the grounding layer 5 and the differential mode signal lines 3a, 3b form therebetween first capacitive coupling c1 (FIG. 3). The first capacitive coupling c1 (FIG. 3) is determined by line width of the differential mode signal lines 3a, 3b and the substrate thickness d of the substrate 1.

The grounding layer 5 forms a boundary edge 51 (FIGS. 1-3) at a location corresponding to the high-frequency connection pads 2 (FIGS. 1, 2) and comprises a grounding pattern structure 6 (FIG. 1) extending from the boundary edge 51 (as also shown in FIGS. 6A-61) in projection direction 12 (FIGS. 1-3) towards the high-frequency connection pads 2a (FIGS. 1-3), 2b in such a way that the grounding pattern structure 6 (as also shown in FIGS. 3, 5, 6, 7) is electrically connected to the grounding layer 5 and forms, via the grounding pattern structure 6, second capacitive coupling c2 (FIG. 3) with respect to the high-frequency connection pads 2a, 2b. The second capacitive coupling c2 (FIG. 3) is related to the surface areas of the high-frequency connection pads 28. 2b, the substrate thickness d of the substrate 1, and the pattern of the grounding pattern structure 6.

Also referring to FIGS. 1 and 5, the grounding pattern structure 6 comprises at least a pair of hollow sections 61a (as also shown in FIGS. 3, 6, 7), 61b (as also shown in FIG. 6) respectively corresponding to the two neighboring high-frequency connection pads 2a, 2b.

With the grounding pattern structure 6 that comprises the hollow sections 61a, 61b, the first capacitive coupling c1 (FIG. 3) formed between the grounding layer 5 (FIG. 1) and the differential mode signal lines 3a, 3b may match the second capacitive coupling c2 (FIG. 3) formed between the grounding pattern structure 6 and the high-frequency connection pads 2a, 2b, whereby in transmitting the high frequency signal S (FIG. 1) carried by the differential mode signal lines 3a, 3b through the extension section 13 (FIG. 1) to the high-frequency connection pads 2a, 2b, impedance match between the two sections can be realized to thereby reduce the potential risk of erroneous transmission of the high-frequency differential mode signal S and ensure the transmission quality of the high frequency signal.

Referring to FIG. 6, a boundary pattern zone 62 (as also shown in FIGS. 1, 6C, 6E, 6G, 6I, 8) may be further provided at a location close to the boundary edge 51 between the grounding layer 5 and the grounding pattern structure 6. In other words, the boundary pattern zone 62 corresponds to a portion close to the connection between the high-frequency connection pads 2a, 2b and the differential mode signal lines 3a, 3b. The boundary pattern zone 62 shown in the drawings is exemplified by a hollow-patterned structure that comprises a plurality of openings and the boundary pattern zone 62 is a size-varying hollow-patterned structure. In other words, the openings of the hollow-patterned structure of the boundary pattern zone 62 that are connected to the grounding layer 5 have smaller opening size and the opening size is larger when getting closer to the projection direction 12 of the high-frequency connection pads 2a, 2b. The boundary pattern zone 62 can alternatively be a hollow-patterned structure that is constituted by a plurality of openings of other geometric structures of one of grid opening, square opening, rectangular opening, rhombus opening, and circular opening.

With the boundary pattern zone 62, the capacitive coupling formed between the grounding layer 5 and the differential mode signal lines 3a, 3b may match the capacitive coupling formed between the boundary pattern zone 62 and the differential mode signal lines 3a, 3b, whereby in transmitting the high frequency signal carried by the differential mode signal lines 3a, 3b through the extension section 13 to the high-frequency connection pads 2a, 2b, impedance match CaO be realized to thereby reduce the potential risk of erroneous transmission of the high-frequency differential mode signal and ensure the transmission quality of the high frequency signal.

The grounding pattern structure 6 can be designed in various other types of pattern structure. For example, FIG. 6A shows that the grounding pattern structure 6a comprises a large-area hollow section 61, and the hollow section 61 corresponds to the two adjacent high-frequency connection pads 2a, 2b and covers the two high-frequency connection pads 2a, 2b. In the connection between the grounding layer 5 and the grounding pattern structure 6a, a boundary pattern zone 62 that has a variable size is provided.

FIG. 6B shows that the grounding pattern structure 6b comprises a hollow-patterned structure that comprises a plurality of square or rectangular hollow structures and a boundary pattern zone 62 that comprises square or rectangular hollows and has a variable size is provided in a connection between the grounding layer 5 and the grounding pattern structure 6b.

FIG. 6C shows a structure similar to FIG. 6B and the difference is that the grounding pattern structure 6c is arranged as a hollow-patterned structure having a variable size. In other words, the hollows of the grounding pattern structure 6c at a location connected to the grounding layer 5 are of a large size and the size of the hollows gets smaller in a direction toward the high-frequency connection pads 2a, 2b.

FIG. 6D shows that the grounding pattern structure 6d comprises hollow-patterned structure comprising a plurality of rhombus hollow-patterned structures and a boundary pattern zone 62 that comprises a plurality of rhombus hollows and has a variable size is provided in the connection between the grounding layer 5 and the grounding pattern structure 6d.

FIG. 6E shows a structure similar to FIG. 6D and the difference is that the grounding pattern structure 6e is arranged as a hollow-patterned structure having a variable size. In other words, the hollows of the grounding pattern structure 6e at a location connected to the grounding layer 5 are of a large size and the size of the hollows gets smaller in a direction toward the high-frequency connection pads 2a, 2b.

FIG. 6F shows that the grounding pattern structure 6f comprises a hollow-patterned structure comprising a plurality of circular hollow-patterned structure and a boundary pattern zone 62 that comprises a plurality of circular hollows and has a variable size is provided in the connection between the grounding layer 5 and the grounding pattern structure 6f.

FIG. 6G shows a structure similar to FIG. 6F and the difference is that the grounding pattern structure 6f is arranged as a hollow-patterned structure having a variable size. In other words, the hollows of the grounding pattern structure 6g at a location connected to the grounding layer 5 are of a large size and the size of the hollows gets smaller in a direction toward the high-frequency connection pads 2a, 2b.

FIG. 6H shows that the grounding pattern structure 6h comprises a grid hollow-patterned structure comprising a plurality of grid openings and a boundary pattern zone 62 that comprises a plurality of grid hollows and has a variable size is provided in the connection between the grounding layer 5 and the grounding pattern structure 6h.

FIG. 6I shows a structure similar to FIG. 6H and the difference is that the grounding pattern structure 6i is arranged as a hollow-patterned structure having a variable size. In other words, the hollows of the grounding pattern structure 6i at a location connected to the grounding layer 5 are of a large size and the size of the hollows gets smaller in a direction toward the high-frequency connection pads 2a, 2b.

Referring to FIG. 7, which is a schematic view showing a circuit board 100 according to the first embodiment of the present invention inserted into a female connector, the female connector 7 is mounted to a circuit board 71. When the circuit board 100 according to the present invention is inserted into an insertion slot 72 of the female connector 7, the high-frequency connection pads 2a, 2b (not shown here) of the circuit board 100 are positioned to respectively engage conductive terminals 73 arranged inside the female connector 7. Under this condition, the grounding layer 5 forms first capacitive coupling with respect to the differential mode signal lines 3a, 3b and the grounding pattern structure 6 forms second capacitive coupling in the manner shown in FIG. 3 with respect to the conductive terminals 73.

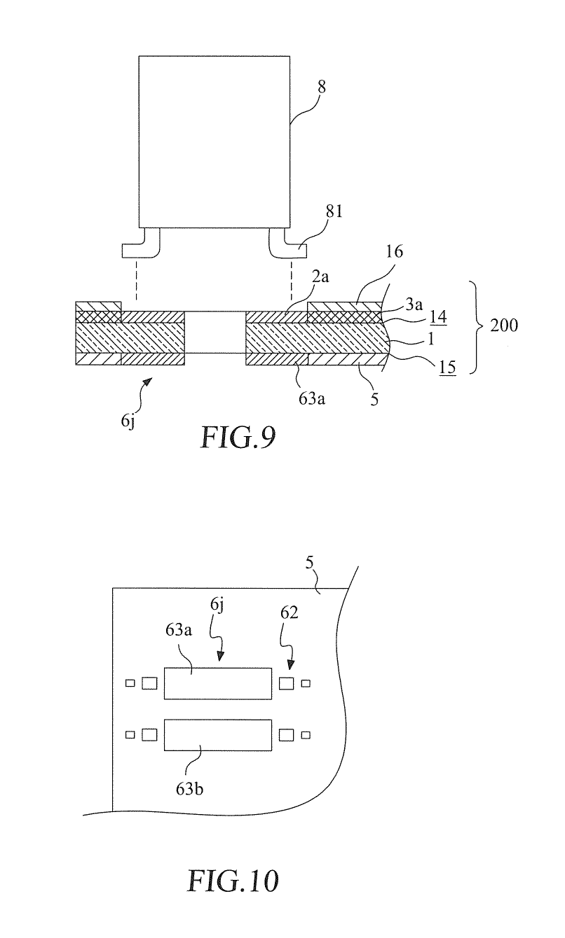

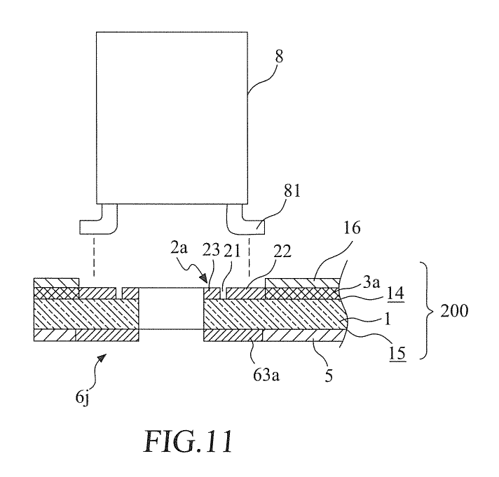

Referring to FIGS. 8 and 9, which are respectively an exploded view and a schematic side elevational view of a second embodiment of the present invention, the instant embodiment provides a circuit board 200 (as also shown in FIG. 11), which is structurally similar to the first embodiment with the difference that at least two rows of a plurality of the connection pads 2 (FIG. 8) are arranged at the first end 11 (FIG. 8) of the component surface 14 of the substrate 1 and a conventional connector 8 or a known integrated circuit device is mounted at a location corresponding to the connection pads 2. The connector 8 comprises signal terminals 81 that are fixed to the connection pads 2 serving as solder pads through soldering with a known solder.

Referring to FIG. 10, the grounding layer 5 comprises a grounding pattern structure 6j (as also shown in FIGS. 8, 9, 11) that comprises hollow sections 63a (as also shown in FIGS. 9, 11), 63b (as also shown in FIG. 8) formed at locations corresponding to the high-frequency connection pads 2a, 2b (FIG. 8). When the connector 8 is positioned on and soldered to the high-frequency connection pads 2a, 2b, the grounding layer 5 forms first capacitive coupling with respect to the differential mode signal lines 3a, 3b and the grounding pattern structure 6j forms second capacitive coupling with respect to the high-frequency connection pads 2a, 2b.

With the arrangement of the grounding pattern structure 6j, a similar result of impedance match between two sections can be achieved in transmitting the high frequency signals carried by the differential mode signal lines 3a, 3b through the extension section 13 to the high-frequency connection pads 2a, 2b, thereby reducing the potential risk of erroneous transmission of the high-frequency differential mode signal and ensuring the transmission quality of the high frequency signal.

The grounding pattern structure 6j according to the instant embodiment can be modified to show different types of patterned structure, similar to those of the previous embodiment shown in FIGS. 6A-6I. For example, the grounding pattern structure 6j can be a hollow-patterned structure comprising a plurality of grid openings, square openings, rectangular openings, rhombus openings, or circular opening, and these hollow-patterned structures may comprise pattern structure of varying sizes.

Similar to the previous embodiment, the connection between the grounding layer 5 and the grounding pattern structure 6j may be provided with a boundary pattern zone 62 (FIGS. 8, 10). The boundary pattern zone 62 corresponds to an adjacent area to the connection between the high-frequency connection pads 2a, 2b and the differential mode signal lines 3a, 3b, whereby capacitive coupling formed between the grounding layer 5 and the differential mode signal lines 3a, 3b can match capacitive coupling formed between the boundary pattern zone 62 and the differential mode signal lines 3a, 3b to thereby reduce the potential risk of erroneous transmission of the high-frequency differential mode signal and ensuring the transmission quality of the high frequency signal.

FIG. 11 shows that the high-frequency connection pads 2a, 2b (not shown herein) can be modified in such a way that an isolation zone 21 is provided between the high-frequency connection pads 2a, 2b (not shown herein) to divide the high-frequency connection pads 2a, 2b (not shown herein) into a reduced high-frequency connection pad section 22 and a preservation section 23 that is isolated from the reduced high-frequency connection pad section 22.

When a connector 8 is mounted to the component surface 14 of the substrate 1, the signal terminals 81 of the connector 8 are soldered to the reduced high-frequency connection pad section 22 only. With the length-reduced high-frequency connection pad section 22 and the grounding pattern structure 6j, the capacitive effect between the high-frequency connection pads 2a, 2b (not shown herein) and the grounding layer 5 can be reduced, while the preservation section 23 may serve as a mechanical reinforcement of the circuit board 200.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A circuit board, comprising:
a substrate having a first end, a second end, and an extension section extending in an extension direction between the first end and the second end, the substrate having a predetermined substrate thickness, the substrate includes a component surface and a grounding surface;
a plurality of high-frequency connection pads formed on the component surface at the first end of the substrate, each of said plurality of high-frequency connection pads being isolated from each other;
a plurality of differential mode signal lines formed on the component surface of the substrate, each of said plurality of differential mode signal lines being isolated from each other and respectively connected to adjacent ones of the plurality high-frequency connection pads, the plurality of differential mode signal lines transmitting at least a high-frequency differential mode signal;
a connector mounded on the component surface of the substrate, including a plurality of high-frequency signal terminals respectively soldered to the high-frequency connection pads;
the grounding surface of the substrate comprising a grounding layer formed at a location aligning and corresponding to the differential mode signal lines, whereby the grounding layer and the differential mode signal lines form a first capacitive coupling therebetween; and
the grounding surface of the substrate including a grounding pattern structure aligned with and corresponding to opposing the high-frequency connection pads and the grounding pattern structure being electrically connected to the grounding layer and forming, with respect to the high-frequency connection pads of the connector, a second capacitive coupling that matches the first capacitive coupling.

2. The circuit board as claimed in claim 1, wherein the grounding pattern structure comprises at least a pair of hollow sections, which respectively correspond to the two adjacent high-frequency connection pads.

3. The circuit board as claimed in claim 1, a boundary pattern zone is formed between the grounding layer and the grounding pattern structure.

4. The circuit board as claimed in claim 1, wherein the circuit board is a flexible circuit board.

5. The circuit board as claimed in claim 1, wherein an insulation cover layer is formed on the component surface of the circuit board and a shielding layer with an impedance control structure is formed on the insulation cover layer.
